(19) United States
(12) Patent Application Publication
(10) Pub. No.: US 2026/0119123 A1
(43) Pub. Date: Apr. 30, 2026

(54) METHOD FOR PERFORMING DIGITAL OPERATIONS WITH AID OF FULL ADDER ARCHITECTURE WITH INPUT/OUTPUT POLARITY INVERSION, AND ASSOCIATED APPARATUS

(71) Applicant: MEDIATEK INC., Hsinchu City (TW)

(72) Inventors: Shih-Che Yen, Hsinchu City (TW); Kin Hooi Dia, Hsinchu City (TW); Hsing-l Tsai, Hsinchu City (TW); Chia-Sheng Yang, Hsinchu City (TW); Ho-Chieh Hsieh, Hsinchu City (TW)

(73) Assignee: MEDIATEK INC., Hsinchu City (TW)

(21) Appl. No.: 19/372,306

(22) Filed: Oct. 29, 2025

Related U.S. Application Data
(60) Provisional application No. 63/714,171, filed on Oct. 31, 2024.

(51) Int. Cl. G06F 7/501; H03K 19/0175

(52) U.S. Cl. CPC G06F 7/501; H03K 19/017545

(57) ABSTRACT

A method for performing digital operations with aid of full adder (FA) architecture with input/output (I/O) polarity inversion and associated apparatus are provided. The method may include: utilizing a first FA, the first FA conforming to a first predetermined FA architecture with output polarity inversion of at least one portion of at least two output signals of the first FA, to output a first output signal among the at least two output signals from a first output pin of the first FA with the output polarity inversion; and utilizing a second FA, the second FA conforming to a second predetermined FA architecture with input polarity inversion of at least one portion of at least three input signals of the second FA, to input the first output signal as first input signal among the at least three input signals into first input pin of the second FA with input polarity inversion.

### CROSS REFERENCE TO RELATED APPLICATIONS

This application claims the benefit of U.S. Provisional Application No. 63/714,171, filed on Oct. 31, 2024. The content of the application is incorporated herein by reference.

### BACKGROUND

The present invention is related to digital processing, and more particularly, to a method for performing digital operations with aid of full adder (FA) architecture with input/output (I/O) polarity inversion, and associated apparatus such as a digital circuit.

According to the related art, multiple sub-circuits operating within a digital circuit may lead to power consumption corresponding to these sub-circuits. For example, when the digital circuit is designed to be more complicated, the number of sub-circuits may increase correspondingly, causing power consumption to become much larger. It seems that there is no proper solution in the related art. Thus, a novel method and associated architecture are needed for solving the problem without introducing any side effect or in a way that is less likely to introduce a side effect.

### SUMMARY

It is an objective of the present invention to provide a method for performing digital operations with aid of FA architecture with I/O polarity inversion, and associated apparatus such as a digital circuit, in order to solve the above-mentioned problem.

At least one embodiment of the present invention provides a method for performing digital operations with aid of FA architecture with I/O polarity inversion, where the method may comprise: utilizing a first FA, the first FA conforming to a first predetermined FA architecture with output polarity inversion of at least one portion of at least two output signals of the first FA, to output a first output signal among the at least two output signals from a first output pin of the first FA with the output polarity inversion; and utilizing a second FA, the second FA conforming to a second predetermined FA architecture with input polarity inversion of at least one portion of at least three input signals of the second FA, to input the first output signal as a first input signal among the at least three input signals into a first input pin of the second FA with the input polarity inversion.

At least one embodiment of the present invention provides a digital circuit for performing digital operations with aid of FA architecture with I/O polarity inversion. For example, the digital circuit may comprise a first FA, the first FA conforming to a first predetermined FA architecture with output polarity inversion of at least one portion of at least two output signals of the first FA, arranged to output a first output signal among the at least two output signals from a first output pin of the first FA with the output polarity inversion. In addition, the digital circuit may further comprise a second FA that is coupled to the first FA via the first output pin of the first FA, the second FA conforming to a second predetermined FA architecture with input polarity inversion of at least one portion of at least three input signals of the second FA, arranged to input the first output signal as a first input signal among the at least three input signals into a first input pin of the second FA with the input polarity inversion.

It is an advantage of the present invention that the method of the present invention, as well as the associated apparatus such as the digital circuit, can decrease power consumption of various digital circuits, and more particularly, can be very helpful on implementing low power adder and multiplier circuits. For example, the method of the present invention and the associated apparatus can provide an innovative carry/sum propagation architecture to reduce the power consumption of the adder and multiplier. In addition, the method of the present invention and the associated apparatus can eliminate the inverter in the carry/sum propagation path through the design of an input-inverted full adder. Additionally, the method of the present invention and the associated apparatus can solve the related art problem without introducing any side effect or in a way that is less likely to introduce a side effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates, in the right half part thereof, a paired-I/O inverter elimination control scheme of a method for performing digital operations with aid of FA architecture with I/O polarity inversion according to an embodiment of the present invention, where a non-inverter-elimination control scheme and a non-paired-I/O inverter elimination control scheme may be illustrated in the left half part of FIG. 1 for better comprehension.

FIG. 2 is a diagram illustrating some implementation details of a FA involved with the paired-I/O inverter elimination control scheme shown in FIG. 1 according to an embodiment of the present invention.

FIG. 3 is a diagram illustrating some implementation details of a FA involved with the paired-I/O inverter elimination control scheme shown in FIG. 1 according to another embodiment of the present invention.

FIG. 4 is a diagram illustrating some implementation details of a FA involved with the paired-I/O inverter elimination control scheme shown in FIG. 1 according to yet another embodiment of the present invention.

FIG. 5 illustrates multiple FAs involved with the paired-I/O inverter elimination control scheme shown in FIG. 1 according to some embodiments of the present invention, where the multiple FAs may conform to various predetermined FA architectures with I/O polarity inversion, respectively.

FIG. 6 illustrates a logic simplification and power reduction control scheme of the method according to an embodiment of the present invention.

FIG. 7A illustrates a set of FAs involved with a multi-input/multi-output logic simplification control scheme of the method according to an embodiment of the present invention.

FIG. 7B illustrates a set of FAs involved with the multi-input/multi-output logic simplification control scheme according to another embodiment of the present invention.

FIG. 8 is a diagram illustrating some implementation details of a FA involved with the paired-I/O inverter elimination control scheme shown in FIG. 1 according to an embodiment of the present invention.

FIG. 9 illustrates a main working flow of the method according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

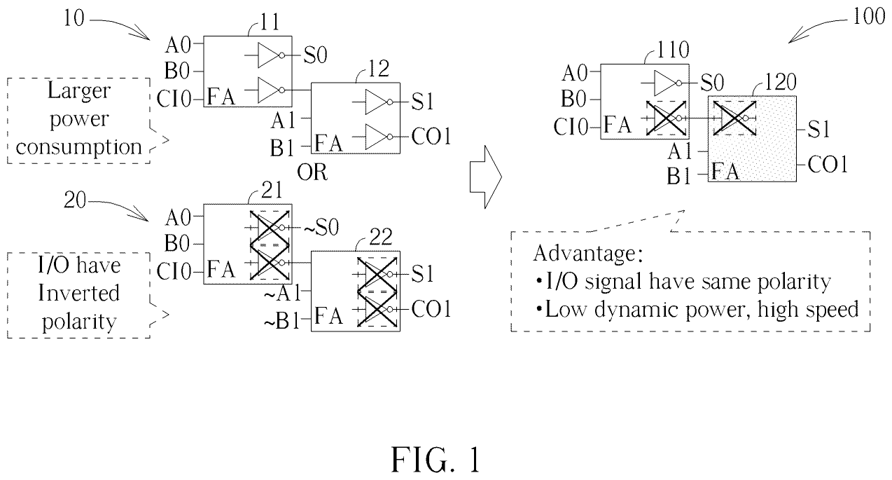

FIG. 1 illustrates, in the right half part thereof, a paired-I/O inverter elimination control scheme of a method for performing digital operations with aid of FA architecture with I/O polarity inversion according to an embodiment of the present invention, where a non-inverter-elimination control scheme and a non-paired-I/O inverter elimination control scheme may be illustrated in the left half part of FIG. 1 for better comprehension. Based on the non-inverter-elimination control scheme shown in the upper left part of FIG. 1, a digital circuit 10 may comprise two FAs 11 and 12 acting as a first stage of circuit (or “the first stage circuit”) and a second stage of circuit (or “the second stage circuit”), respectively. For example, the FA 11 may have three input pins for inputting two operand signals A0 and B0 and a carry-input (CI) signal CI0, as well as two output pins for outputting a sum-output signal S0 and a carry-output (CO) signal. In addition, the FA 12 may have three input pins for inputting two operand signals A1 and B1 and a carry-input signal, as well as two output pins for outputting a sum-output signal S1 and a carry-output signal CO1. As the pin for inputting the carry-input signal by the FA 12 is electrically connected to the pin for outputting the carry-output signal by the FA 11, the FA 12 can receive the carry-output signal from the FA 11 to be the carry-input signal. In the FA11, there are two inverters on the signal paths toward the two output pins for outputting the sum-output signal S0 and the carry-output signal thereof, and similarly, in the FA12, there are two inverters on the signal paths toward the two output pins for outputting the sum-output signal S1 and the carry-output signal CO1. Among all the of control schemes shown in FIG. 1, the existence of these inverters of the two FAs 11 and 12 in the non-inverter-elimination control scheme may result in larger power consumption than the other control schemes. When the digital circuit 10 is designed to be more complicated, the number of sub-circuits (e.g., FAs) may increase correspondingly, causing the overall power consumption to become much larger.

Based on the non-paired-I/O inverter elimination control scheme shown in the lower left part of FIG. 1, a digital circuit 20 may comprise two FAs 21 and 22 that are implemented by changing the FA architecture of the two FAs 11 and 12, respectively, to act as the first stage circuit and the second stage circuit, respectively. More particularly, regarding the two FAs 21 and 22 that are implemented by changing the FA architecture of the two FAs 11 and 12, the inverters on the signal paths toward the output pins are removed, respectively (labeled “X” on the inverters for indicating the removal of the inverters for better comprehension), and therefore, the associated I/O signals are forced to have inverted polarity thereof, respectively (labeled “I/O have Inverted polarity” for brevity). For example, after changing the FA architecture of the two FAs 11 and 12 to obtain the two FAs 21 and 22, respectively, the sum-output signal S0 and the two operand signals A1 and B1 mentioned above should become the sum-output signal ˜S0 and the two operand signals ˜A1 and ˜B1 having the inverted polarity in the non-paired-I/O inverter elimination control scheme, respectively, causing inconvenience of using the FAs 21 and 22 in the digital circuit 20.

Based on the paired-I/O inverter elimination control scheme, a digital circuit for performing digital operations with aid of FA architecture with I/O polarity inversion, such as the digital circuit 100 shown in the right half part of FIG. 1, may comprise a first FA (e.g., the FA 110) conforming to a first predetermined FA architecture with output polarity inversion of at least one portion (e.g., a portion or all) of at least two output signals of the first FA, for outputting a first output signal among the aforementioned at least two output signals from a first output pin of the first FA with the output polarity inversion, and may further comprise a second FA (e.g., the FA 120) conforming to a second predetermined FA architecture with input polarity inversion of at least one portion (e.g., a portion or all) of at least three input signals of the second FA, for inputting the first output signal as a first input signal among the aforementioned at least three input signals into a first input pin of the second FA with the input polarity inversion. In addition, the second FA (e.g., the FA 120) may be coupled to the first FA (e.g., the FA 110) via the first output pin of the first FA, in particular, via at least both of the first output pin of the first FA and the first input pin of the second FA, where the first output signal of the first FA (e.g., the FA 110) and the first input signal of the second FA (e.g., the FA 120) have the same polarity at the first output pin of the first FA and the first input pin of the second FA, respectively.

More particularly, the second FA (e.g., the FA 120) and the first FA (e.g., the FA 110) conform to the second predetermined FA architecture and the first predetermined FA architecture with the I/O polarity inversion, respectively, for inverter elimination on the respective internal signal paths of the first FA and the second FA with respect to the first output signal and the first input signal while keeping the same polarity of I/O pins, such as the I/O pins comprising both of the first input pin and the first output pin. Taking the electrical connection between the two FAs 110 and 120 as shown in the right half part of FIG. 1 as an example, an inverter on a first internal signal path of the first FA like the FA 110, such as the first internal signal path toward the output pin for outing the carry-output signal, and an inverter on a second internal signal path of the second FA like the FA 120, such as the second internal signal path from the input pin for inputting the carry-input signal, may have been removed or eliminated (labeled “X” on the inverters for indicating the elimination of the inverters for better comprehension), but the present invention is not limited thereto. In some examples, no matter whether the electrical connection between the first and the second FAs is implemented via the carry path and/or the sum path, the inverter on the first internal signal path of the first FA, such as the first internal signal path toward the first output pin for outing the first output signal (e.g., any output signal among the carry-output signal and the sum-output signal), and the inverter on the second internal signal path of the second FA, such as the second internal signal path from the first input pin for inputting the first input signal (e.g., any input signal among the carry-input signal and the two operand signals) may have been eliminated in a paired-I/O inverter elimination manner for solving the problems of the non-inverter-elimination control scheme, the non-paired-I/O inverter elimination control scheme, etc. In comparison with the non-inverter-elimination control scheme, the inverter elimination in the carry/sum path with keeping the same polarity of the input/output pins (e.g., the first input pin and the first output pin) corresponding to the same electrical connection such as the aforementioned electrical connection between the two FAs 110 and 120 in accordance with the paired-I/O inverter elimination control scheme can reduce the power consumption, without introducing any side effect such as the issue of the I/O signals having inverted polarity as in the non-paired-I/O inverter elimination control scheme.

The method and the associated apparatus such as the digital circuit 100 can achieve low dynamic power and high speed with ease while keeping the I/O signals have same polarity, and therefore can be very helpful on implementing low power adder and multiplier circuits. For example, the method of the present invention and the associated apparatus can provide an innovative carry/sum propagation architecture to reduce the power consumption of the adder and multiplier. In addition, the method of the present invention and the associated apparatus such as the digital circuit 100 can eliminate the inverter in the carry/sum propagation path through the design of an input-inverted full adder.

TABLE 1

| | |
|---|---|
| Input | Output |

| A | B | CI (Cᵢₙ) | CO (Cₒᵤₜ) | S (Sum) |
|---|---|---|---|---|
| 0 | 0 | 0 | 0 | 0 |
| 1 | 0 | 0 | 0 | 1 |
| 0 | 1 | 0 | 0 | 1 |
| 1 | 1 | 0 | 1 | 0 |
| 0 | 0 | 1 | 0 | 1 |
| 1 | 0 | 1 | 1 | 0 |
| 0 | 1 | 1 | 1 | 0 |
| 1 | 1 | 1 | 1 | 1 |

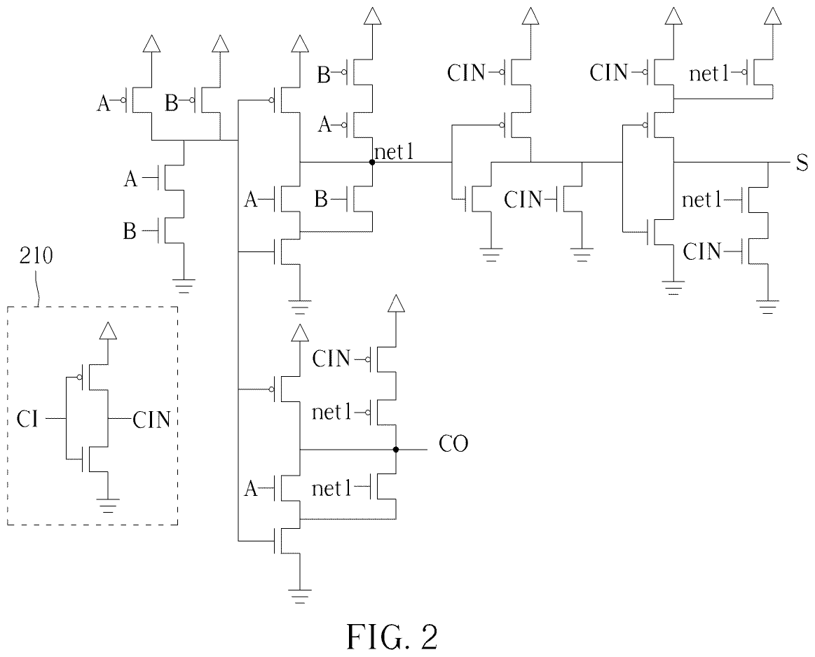

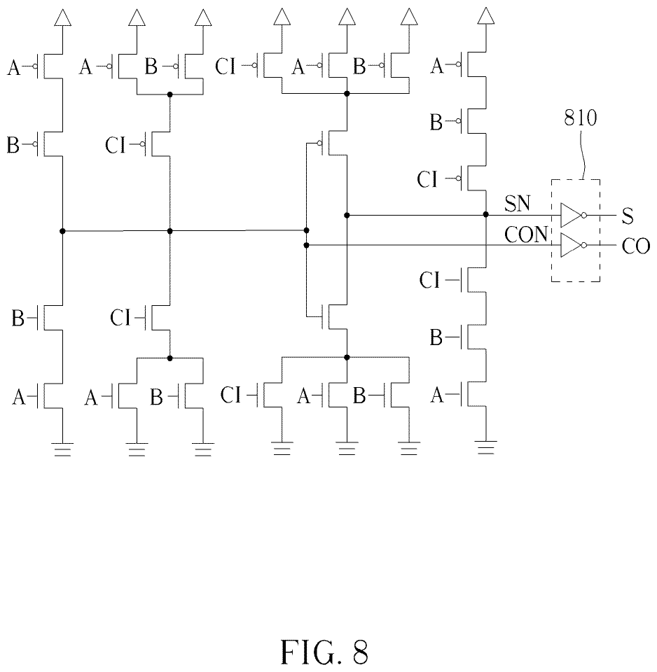

Table 1 illustrates an example of a truth table of any FA among a plurality of FAs, and the plurality of FAs can be indexed as the plurality of FAs {FA(i)|i=0, 1, . . . } such as the FAs {FA(0), FA(1), . . . }, where the inputs of the aforementioned any FA such as the FA FA(i) comprise the operand signals A(i) and B(i) and the carry-input signal CI(i) (or Cᵢₙ(i)), which can also be referred to as the operand signals A and B and the carry-input signal CI (or Cᵢₙ), respectively, and the outputs of the aforementioned any FA such as the FA FA(i) comprise the carry-output signal CO(i) (or Cₒᵤₜ(i)) and the sum-output signal S(i) (or Sum(i)), which can also be referred to as the carry-output signal CO (or Cₒᵤₜ) and the sum-output signal S (or Sum), respectively, but the present invention is not limited thereto. According to some embodiments, the operand signals A(i) and B(i), the carry-input signal CI(i) (or Cᵢₙ(i)), the carry-output signal CO(i) (or Cₒᵤₜ(i)) and the sum-output signal S(i) (or Sum(i)) can be rewritten in the simplified form thereof, respectively. For example, when i=0, the operand signals A(i) and B(i), the carry-input signal CI(i) (or Cᵢₙ(i)), the carry-output signal CO(i) (or Cₒᵤₜ(i)) and the sum-output signal S(i) (or Sum(i)) can be rewritten as the operand signals A0 and B0, the carry-input signal CI0 (or Cᵢₙ0), the carry-output signal CO0 (or Cₒᵤₜ0) and the sum-output signal S0 (or Sum0), respectively; when i=1, the operand signals A(i) and B(i), the carry-input signal CI(i) (or Cᵢₙ(i)), the carry-output signal CO(i) (or Cₒᵤₜ(i)) and the sum-output signal S(i) (or Sum(i)) can be rewritten as the operand signals A1 and B1, the carry-input signal CI1 (or Cᵢₙ1), the carry-output signal CO1 (or Cₒᵤₜ1) and the sum-output signal S1 (or Sum1), respectively; and the rest can be deduced by analogy. In addition, for any I/O signal among the operand signals A and B, the carry-input signal CI (or Cᵢₙ), the carry-output signal CO (or Cₒᵤₜ) and the sum-output signal S (or Sum) of the aforementioned any FA such as the FA FA(i), if there is a corresponding I/O signal having an opposite polarity which is opposite to the polarity of the aforementioned any I/O signal, the corresponding I/O signal can be named by the same symbol plus either a prefix “˜” or a suffix “N” (e.g., the sum-output signal ˜S0 and the two operand signals ˜A1 and ˜B1 shown in FIG. 1, or the carry-input signal CIN and the operand signals BN and AN respectively shown in FIG. 2 to FIG. 4 as well as the carry-output signal CON and the sum-output signal SN shown in FIG. 8).

FIG. 2 is a diagram illustrating some implementation details of a FA involved with the paired-I/O inverter elimination control scheme shown in FIG. 1 according to an embodiment of the present invention. For example, the FA may comprise multiple transistors such as metal-oxide-semiconductor field-effect transistors (MOSFETs), including N-type MOSFETs (NMOSFETs) and P-type MOSFETs (PMOSFETs), and some transistors among them have their gates coupled to the node net1 while some others transistors among them have their gates coupled to the operand signals A and B and the carry-input signals CI and CIN, respectively. The FA shown in FIG. 2 and the FA architecture thereof can be taken as examples of the second FA (or the FA acting as the second stage circuit) and the second predetermined FA architecture, respectively. In particular, a partial FA architecture such as the inverter 210 shown in FIG. 2 in this FA architecture can be eliminated to allow the remaining partial FA architecture to be used as the second FA (or the FA acting as the second stage circuit), where the operand signals A and B and the carry-input signal CIN (e.g., the carry-input signal CIN having an opposite polarity which is opposite to the polarity of the carry-input signal CI in the inverter 210) in this FA architecture can be used as the operand signals A and B and the carry-input signal CIN of the second FA, respectively, and the carry-output signal CO and the sum-output signal S in this FA architecture can be used as the carry-output signal CO and the sum-output signal S of the second FA, respectively.

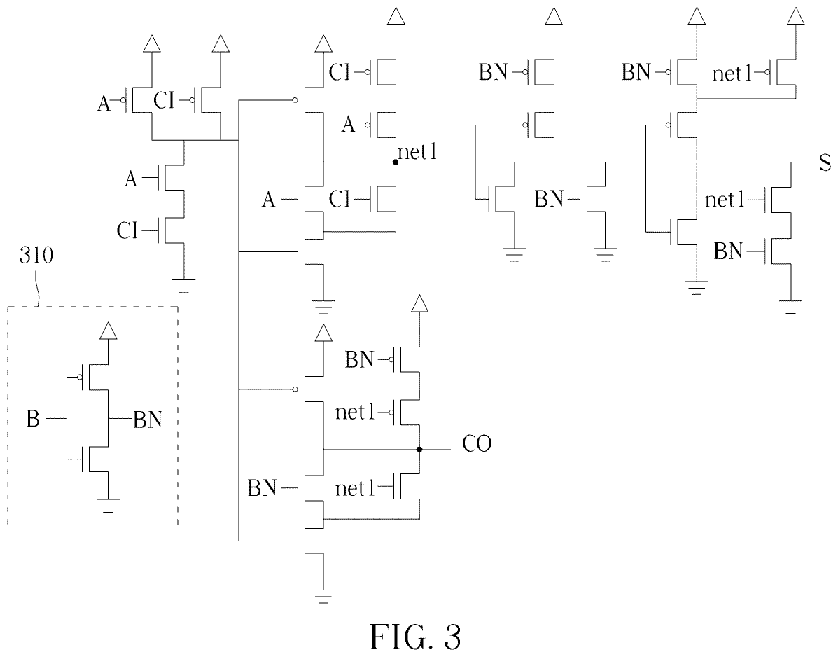

FIG. 3 is a diagram illustrating some implementation details of a FA involved with the paired-I/O inverter elimination control scheme shown in FIG. 1 according to another embodiment of the present invention. For example, the FA may comprise multiple transistors such as MOSFETs, including NMOSFETs and PMOSFETs, and some transistors among them have their gates coupled to the node net1 while some others transistors among them have their gates coupled to the operand signals A, B and BN and the carry-input signal CI, respectively. The FA shown in FIG. 3 and the FA architecture thereof can be taken as examples of the second FA (or the FA acting as the second stage circuit) and the second predetermined FA architecture, respectively. In particular, a partial FA architecture such as the inverter 310 shown in FIG. 3 in this FA architecture can be eliminated to allow the remaining partial FA architecture to be used as the second FA (or the FA acting as the second stage circuit), where the operand signal A, the operand signal BN (e.g., the operand signal BN having an opposite polarity which is opposite to the polarity of the operand signal B in the inverter 310) and the carry-input signal CI in this FA architecture can be used as the operand signal A, the operand signal BN and the carry-input signal CI of the second FA, respectively, and the carry-output signal CO and the sum-output signal S in this FA architecture can be used as the carry-output signal CO and the sum-output signal S of the second FA, respectively.

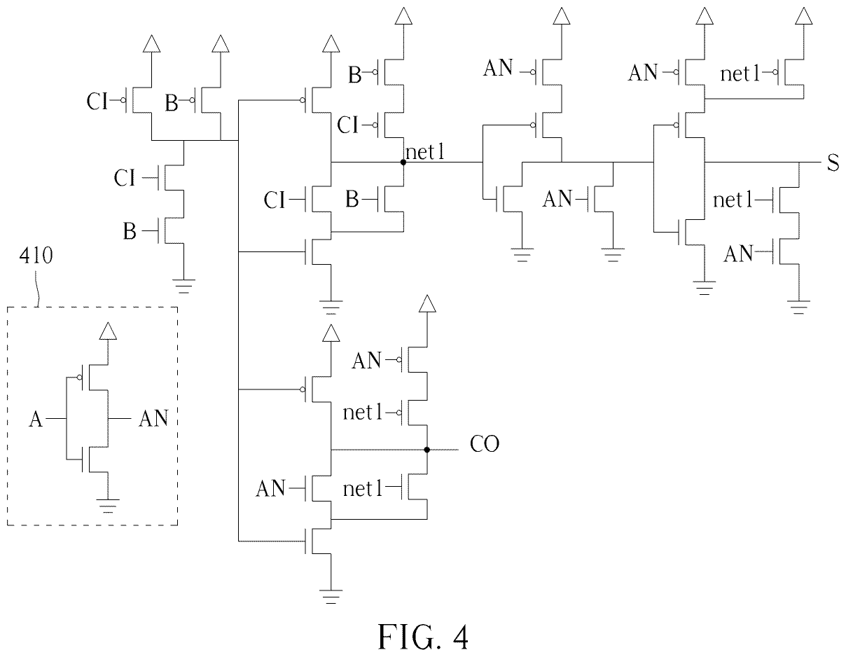

FIG. 4 is a diagram illustrating some implementation details of a FA involved with the paired-I/O inverter elimination control scheme shown in FIG. 1 according to yet another embodiment of the present invention. For example, the FA may comprise multiple transistors such as MOSFETs, including NMOSFETs and PMOSFETs, and some transistors among them have their gates coupled to the node net1 while some others transistors among them have their gates coupled to the operand signals A, AN and B and the carry-input signal CI, respectively. The FA shown in FIG. 4 and the FA architecture thereof can be taken as examples of the second FA (or the FA acting as the second stage circuit) and the second predetermined FA architecture, respectively. In particular, a partial FA architecture such as the inverter 410 shown in FIG. 4 in this FA architecture can be eliminated to allow the remaining partial FA architecture to be used as the second FA (or the FA acting as the second stage circuit), where the operand signal AN (e.g., the operand signal AN having an opposite polarity which is opposite to the polarity of the operand signal A in the inverter 410), the operand signal B and the carry-input signal CI in this FA architecture can be used as the operand signal AN, the operand signal B and the carry-input signal CI of the second FA, respectively, and the carry-output signal CO and the sum-output signal S in this FA architecture can be used as the carry-output signal CO and the sum-output signal S of the second FA, respectively.

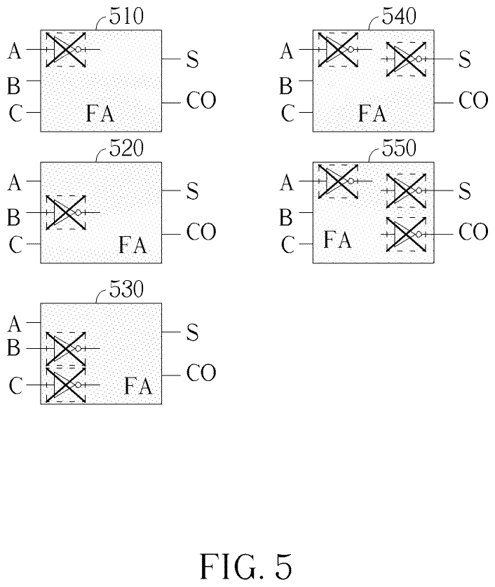

FIG. 5 illustrates multiple FAs 510, 520, 530, 540 and 550 involved with the paired-I/O inverter elimination control scheme shown in FIG. 1 according to some embodiments of the present invention, where the multiple FAs 510, 520, 530, 540 and 550 may conform to various predetermined FA architectures with the I/O polarity inversion, respectively, but the present invention is not limited thereto. The FA inversion architectures (arc) can be any FA architecture among the FA architectures with various kinds of I/O polarity inversion (e.g., the I/O polarity inversion of one or more inputs, the I/O polarity inversion of one or more outputs, as well as the I/O polarity inversion of one or more inputs and one or more outputs).

The output polarity inversion of the aforementioned at least one portion of the aforementioned at least two output signals (e.g., the carry-output signal CO and the sum-output signal S) of the first FA (or the FA acting as the second stage circuit) may represent first output polarity inversion regarding the first FA, and no matter whether there is any first input polarity inversion regarding the first FA or not, the input polarity inversion of the aforementioned at least one portion of the aforementioned at least three input signals (e.g., the operand signals A and B and the carry-input signal CI) of the second FA (or the FA acting as the second stage circuit) may represent second input polarity inversion regarding the second FA. In particular, for the second FA conforming to the second predetermined FA architecture with the second input polarity inversion, at least one inverter on at least one internal signal path thereof from at least one input pin for inputting at least one input signal (e.g., the operand signal A, the operand signal B, and/or the carry-input signal CI) may have been eliminated with respect to the first FA conforming to the first predetermined FA architecture with the first output polarity inversion in the paired-I/O inverter elimination manner, to make the aforementioned at least one input signal become at least one corresponding input signal (e.g., the operand signal AN, the operand signal BN, and/or the carry-input signal CIN). Examples of the second FA conforming to the second predetermined FA architecture may include but not limited to: the FA 120 shown in FIG. 1 as well as the FAs 510, 520, 530, 540 and 550 shown in FIG. 5.

In addition, the second FA (or the FA acting as the second stage circuit) may further conform to a third predetermined FA architecture with both of the second input polarity inversion regarding the second FA, such as the input polarity inversion of the aforementioned at least one portion of the aforementioned at least three input signals, and second output polarity inversion regarding the second FA, such as the second output polarity inversion of at least one output signal (e.g., the carry-output signal CO and the sum-output signal S) of the second FA, for outputting the aforementioned at least one output signal from at least one output pin of the second FA with the second output polarity inversion. In particular, for the second FA conforming to the third predetermined FA architecture with both of the second input polarity inversion and the second output polarity inversion, at least one inverter on at least one internal signal path thereof from/toward at least one I/O pin for inputting/outputting at least one I/O signal (e.g., the operand signal A, the operand signal B, and/or the carry-input signal CI, as well as the carry-output signal CO and/or the sum-output signal S) may have been eliminated with respect to the adjacent FA (e.g., the first FA acting as the previous stage of the second FA, or another FA acting as the next stage of the second FA) conforming to the predetermined FA architecture thereof with the I/O polarity inversion in the paired-I/O inverter elimination manner, to make the aforementioned at least one I/O signal become at least one corresponding I/O signal (e.g., the operand signal AN, the operand signal BN, and/or the carry-input signal CIN, as well as the carry-output signal CON and/or the sum-output signal SN). Examples of the second FA conforming to the third predetermined FA architecture may include but not limited to: the FAs 540 and 550 shown in FIG. 5.

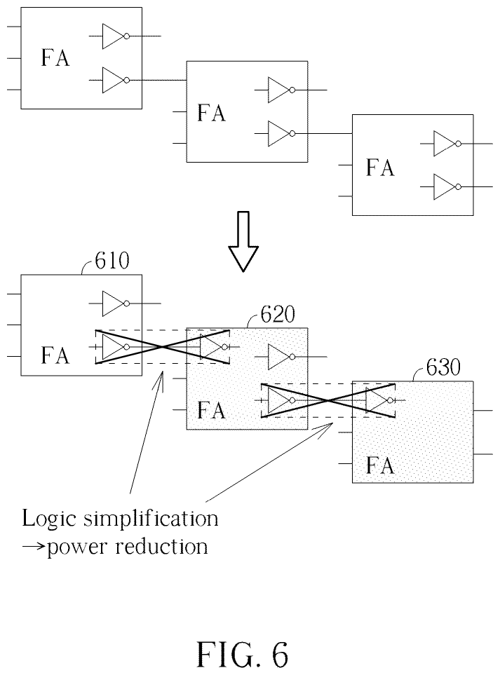

FIG. 6 illustrates a logic simplification and power reduction control scheme of the method according to an embodiment of the present invention. The aforementioned digital circuit such as the digital circuit 100 may comprise the plurality of FAs {FA(i)|i=0, 1, . . . } such as the FAs {FA(0), FA(1), . . . }. More particularly, within the aforementioned digital circuit, a series of FAs corresponding to more than two bits among the plurality of FAs {FA(i)|i=0, 1, . . . } may comprise the first FA (or the FA acting as the second stage circuit), the second FA (or the FA acting as the second stage circuit) and a third FA (or the FA acting as a third of stage circuit, referred to as “the third stage circuit” for brevity) in series, such as the FAs 610, 620 and 630 in series, where the second FA can be electrically connected to multiple different type FAs which are multiple FA of a different type, with the multiple different type FAs comprising the first FA and the third FA, for achieving logic simplification, but the present invention is not limited thereto. According to some embodiments, the circuit architecture of the digital circuit may vary. For example, the second FA can be electrically connected to at least one different type FA which is at least one FA of the different type, with the aforementioned at least one different type FA comprising the first FA, for achieving the logic simplification.

The first FA (or the FA acting as the second stage circuit) such as the FA 610 may conform to the first predetermined FA architecture with the first output polarity inversion, and the second FA (or the FA acting as the second stage circuit) such as the FA 620 may conform to the second predetermined FA architecture with the second input polarity inversion. For the two FAs 620 and 610, as at least two inverters on the associated internal signal paths thereof from/toward the I/O pins for inputting/outputting the associated I/O signals on the electrical connection between the FAs 620 and 610 may have been eliminated, the aforementioned digital circuit such as the digital circuit 100 can achieve the logic simplification as well as the power reduction corresponding to the logic simplification. In addition, the second FA (or the FA acting as the second stage circuit) such as the FA 620 may further conform to the third predetermined FA architecture with both of the second input polarity inversion and the second output polarity inversion, and the third FA (or the FA acting as the third stage circuit) such as the FA 630 may conform to at least one predetermined FA architecture (e.g., a predetermined FA architecture similar to or the same as the second predetermined FA architecture) with the third input polarity inversion regarding the third FA. For the two FAs 630 and 620, as at least two inverters on the associated internal signal paths thereof from/toward the I/O pins for inputting/outputting the associated I/O signals on the electrical connection between the FAs 630 and 620 may have been eliminated, the aforementioned digital circuit such as the digital circuit 100 can achieve the logic simplification as well as the power reduction corresponding to the logic simplification. For brevity, similar descriptions for this embodiment are not repeated in detail here.

Based on a multi-input/multi-output logic simplification control scheme of the method, at least one among the aforementioned at least one portion of the aforementioned at least two output signals (e.g., the carry-output signal CO/CON and the sum-output signal S/SN) and the aforementioned at least one portion of the aforementioned at least three input signals (e.g., the operand signal A/AN, the operand signal B/BN and the carry-input signal CI/CIN) may comprise multiple signals, for achieving multi-input/multi-output logic simplification.

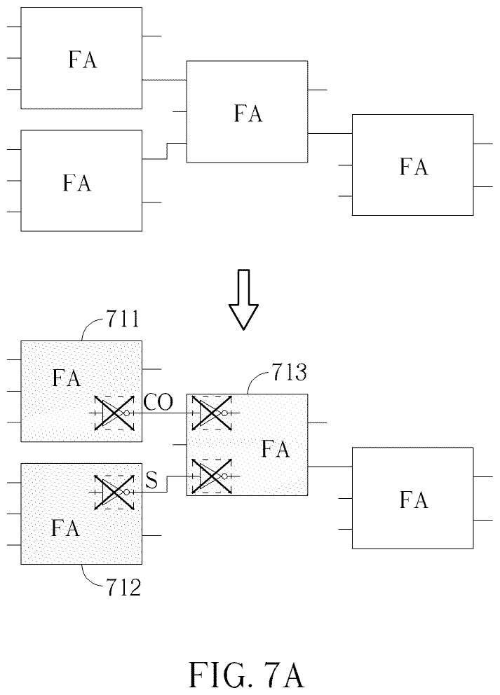

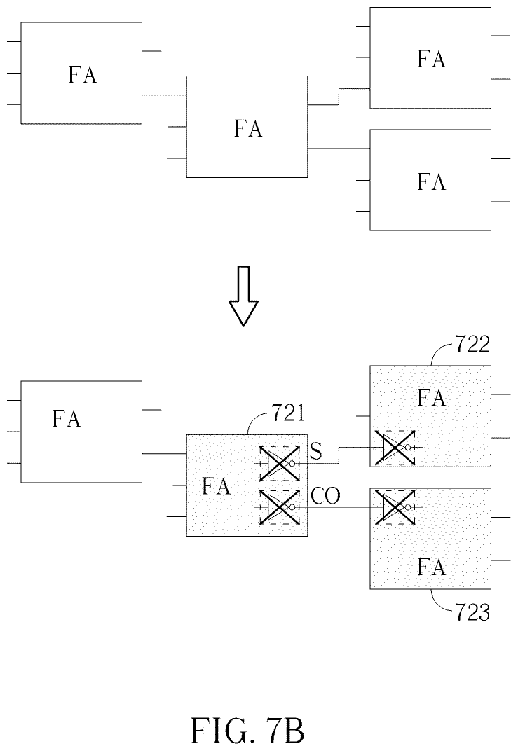

FIG. 7A illustrates a set of FAs (e.g., the FAs 711, 712 and 713) involved with the multi-input/multi-output logic simplification control scheme of the method according to an embodiment of the present invention. For the case that the aforementioned at least one portion of the aforementioned at least three input signals (e.g., the operand signal A/AN, the operand signal B/BN and the carry-input signal CI/CIN) comprise multiple signals for achieving the multi-input/multi-output logic simplification, the FAs 711 and 712 can be taken as examples of the first FA (or the FA acting as the first stage circuit), and the FA 713 can be taken as an example of the second FA (or the FA acting as the second stage circuit). For brevity, similar descriptions for this embodiment are not repeated in detail here.

FIG. 7B illustrates a set of FAs (e.g., the FAs 721, 722 and 723) involved with the multi-input/multi-output logic simplification control scheme according to another embodiment of the present invention. For the case that the aforementioned at least one portion of the aforementioned at least two output signals (e.g., the carry-output signal CO/CON and the sum-output signal S/SN) comprise multiple signals for achieving the multi-input/multi-output logic simplification, the FA 721 can be taken as an example of the first FA (or the FA acting as the first stage circuit), and the FAs 722 and 723 can be taken as examples of the second FA (or the FA acting as the second stage circuit). For brevity, similar descriptions for this embodiment are not repeated in detail here.

FIG. 8 is a diagram illustrating some implementation details of a FA involved with the paired-I/O inverter elimination control scheme shown in FIG. 1 according to an embodiment of the present invention. For example, the FA may comprise multiple transistors such as MOSFETs, including NMOSFETs and PMOSFETs, and some transistors among them have their gates coupled to the operand signals A and B and the carry-input signal CI, respectively. The FA shown in FIG. 8 and the FA architecture thereof can be taken as examples of the first FA (or the FA acting as the first stage circuit) and the first predetermined FA architecture, respectively. In particular, a partial FA architecture such as at least one inverter (e.g., one or more inverters) among the inverters 810 shown in FIG. 8 in this FA architecture can be eliminated to allow the remaining partial FA architecture to be used as the second FA (or the FA acting as the second stage circuit), where the operand signals A and B and the carry-input signal CI in this FA architecture can be used as the operand signals A and B and the carry-input signal CI of the second FA, respectively. For example, when the upper inverter on the sum path among the inverters 810 is eliminated to allow the remaining partial FA architecture to be used as the second FA, the carry-output signal CO and the sum-output signal SN (e.g., the sum-output signal SN having an opposite polarity which is opposite to the polarity of the sum-output signal S in the inverters 810) in this FA architecture can be used as the carry-output signal CO and the sum-output signal SN of the second FA, respectively. In another example, when the lower inverter on the carry path among the inverters 810 is eliminated to allow the remaining partial FA architecture to be used as the second FA, the carry-output signal CON (e.g., the carry-output signal CON having an opposite polarity which is opposite to the polarity of the carry-output signal CO in the inverters 810) and the sum-output signal S in this FA architecture can be used as the carry-output signal CON and the sum-output signal S of the second FA, respectively. In yet another example, when both of the inverters 810 are eliminated to allow the remaining partial FA architecture to be used as the second FA, the carry-output signal CON and the sum-output signal SN (e.g., the carry-output signal CON and the sum-output signal SN with the polarity thereof opposite to that of the carry-output signal CO and the sum-output signal S in the inverters 810, respectively) in this FA architecture can be used as the carry-output signal CON and the sum-output signal SN of the second FA, respectively.

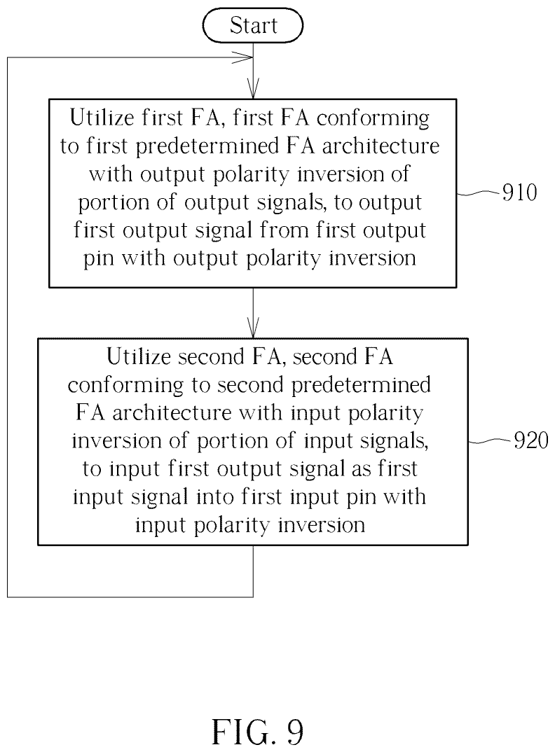

FIG. 9 illustrates a main working flow of the method according to an embodiment of the present invention. The aforementioned digital circuit for performing the digital operations with the aid of the FA architecture with the I/O polarity inversion, such as the digital circuit 100 shown in FIG. 1, can operate according to the working flow shown in FIG. 9.

In Step 910, the digital circuit (e.g., the digital circuit 100) can utilize the first FA (e.g., the FA 110) conforming to the first predetermined FA architecture with the output polarity inversion of the aforementioned at least one portion (e.g., a portion or all) of the aforementioned at least two output signals of the first FA, for outputting the first output signal among the aforementioned at least two output signals from the first output pin of the first FA with the output polarity inversion.

In Step 920, the digital circuit (e.g., the digital circuit 100) can utilize the second FA (e.g., the FA 120) conforming to the second predetermined FA architecture with the input polarity inversion of the aforementioned at least one portion (e.g., a portion or all) of the aforementioned at least three input signals of the second FA, for inputting the first output signal as the first input signal among the aforementioned at least three input signals into the first input pin of the second FA with the input polarity inversion.

More particularly, two FAs {(FA(i−1), FA(i))|i>0} among the plurality of FAs {FA(i) i=0, 1, . . . } may represent two adjacent FAs FA(i−1) and FA(i) in series. Taking the two adjacent FAs FA(i−1) and FA(i) as examples of the first FA and the second FA, respectively, the aforementioned at least two output signals may comprise a first sum-output signal such as the sum-output signal S(i−1) (or Sum(i−1)) and a first carry-output signal such as the carry-output signal CO(i−1) (or Cₒᵤₜ(i−1)), and the first output signal may represent any output signal among the first sum-output signal and the first carry-output signal, such as a certain signal among the sum-output signal S(i−1) (or Sum(i−1)) and the carry-output signal CO(i−1) (or Cₒᵤₜ(i−1)). In addition, the aforementioned at least three input signals may comprise a first operand signal such as the operand signal A(i), a second operand signal such as the operand signal B(i), and a carry-input signal such as the carry-input signal CI(i) (or Cᵢₙ(i)), and the first input signal may represent any input signal among the first operand signal, the second operand signal and the carry-input signal, such as a certain signal among the operand signal A(i), the operand signal B(i) and the carry-input signal CI(i) (or Cᵢₙ(i)). For brevity, similar descriptions for this embodiment are not repeated in detail here.

For better comprehension, the method may be illustrated with the working flow shown in FIG. 9, but the present invention is not limited thereto. According to some embodiments, one or more steps may be added, deleted, or changed in the working flow shown in FIG. 9.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A digital circuit, for performing digital operations with aid of full adder (FA) architecture with input/output (I/O) polarity inversion, the digital circuit comprising:
a first FA, the first FA conforming to a first predetermined FA architecture with output polarity inversion of at least one portion of at least two output signals of the first FA, arranged to output a first output signal among the at least two output signals from a first output pin of the first FA with the output polarity inversion; and
a second FA, coupled to the first FA via the first output pin of the first FA, the second FA conforming to a second predetermined FA architecture with input polarity inversion of at least one portion of at least three input signals of the second FA, arranged to input the first output signal as a first input signal among the at least three input signals into a first input pin of the second FA with the input polarity inversion.

2. The digital circuit of claim 1, wherein the second and the first FAs conform to the second and the first predetermined FA architectures with the I/O polarity inversion, respectively, for inverter elimination on respective internal signal paths of the first and the second FAs with respect to the first output signal and the first input signal while keeping a same polarity of I/O pins, the I/O pins comprising the first input and the first output pins.

3. The digital circuit of claim 1, wherein the output polarity inversion of the at least one portion of the at least two output signals of the first FA represents first output polarity inversion regarding the first FA; and the second FA further conforms to a third predetermined FA architecture with both of the input polarity inversion of the at least one portion of the at least three input signals and second output polarity inversion regarding the second FA, the second output polarity inversion of at least one output signal of the second FA, for outputting the at least one output signal from at least one output pin of the second FA with the second output polarity inversion.

4. The digital circuit of claim 1, wherein a series of FAs corresponding to more than two bits within the digital circuit comprises the first FA, the second FA and a third FA in series.

5. The digital circuit of claim 1, wherein the second FA is electrically connected to at least one different type FA which is at least one FA of a different type, the at least one different type FA comprising the first FA, for achieving logic simplification.

6. The digital circuit of claim 1, wherein at least one among the at least one portion of the at least two output signals and the at least one portion of the at least three input signals comprise multiple signals, for achieving multi-input/multi-output logic simplification.

7. The digital circuit of claim 1, wherein the at least two output signals comprise a first sum-output signal and a first carry-output (CO) signal, and the first output signal represents any output signal among the first sum-output signal and the first carry-output signal.

8. The digital circuit of claim 7, wherein the at least three input signals comprise a first operand signal, a second operand signal and a carry-input (CI) signal, and the first input signal represents any input signal among the first operand signal, the second operand signal and the carry-input signal.

9. The digital circuit of claim 1, wherein the at least three input signals comprise a first operand signal, a second operand signal and a carry-input (CI) signal, and the first input signal represents any input signal among the first operand signal, the second operand signal and the carry-input signal.

10. The digital circuit of claim 1, wherein the second FA is coupled to the first FA via at least both of the first output pin of the first FA and the first input pin of the second FA, wherein the first output signal of the first FA and the first input signal of the second FA have a same polarity at the first output pin of the first FA and the first input pin of the second FA, respectively.

11. A method for performing digital operations with aid of full adder (FA) architecture with input/output (I/O) polarity inversion, the method comprising:
utilizing a first FA, the first FA conforming to a first predetermined FA architecture with output polarity inversion of at least one portion of at least two output signals of the first FA, to output a first output signal among the at least two output signals from a first output pin of the first FA with the output polarity inversion; and
utilizing a second FA, the second FA conforming to a second predetermined FA architecture with input polarity inversion of at least one portion of at least three input signals of the second FA, to input the first output signal as a first input signal among the at least three input signals into a first input pin of the second FA with the input polarity inversion.

12. The method of claim 11, wherein the second and the first FAs conform to the second and the first predetermined FA architectures with the I/O polarity inversion, respectively, for inverter elimination on respective internal signal paths of the first and the second FAs with respect to the first output signal and the first input signal while keeping a same polarity of I/O pins, the I/O pins comprising the first input and the first output pins.

13. The method of claim 11, wherein the output polarity inversion of the at least one portion of the at least two output signals of the first FA represents first output polarity inversion regarding the first FA; and the second FA further conforms to a third predetermined FA architecture with both of the input polarity inversion of the at least one portion of the at least three input signals and second output polarity inversion regarding the second FA, the second output polarity inversion of at least one output signal of the second FA, for outputting the at least one output signal from at least one output pin of the second FA with the second output polarity inversion.

14. The method of claim 11, wherein a series of FAs corresponding to more than two bits within the digital circuit comprises the first FA, the second FA and a third FA in series.

15. The method of claim 11, wherein the second FA is electrically connected to at least one different type FA which is at least one FA of a different type, the at least one different type FA comprising the first FA, for achieving logic simplification.

16. The method of claim 11, wherein at least one among the at least one portion of the at least two output signals and the at least one portion of the at least three input signals comprise multiple signals, for achieving multi-input/multi-output logic simplification.

17. The method of claim 11, wherein the at least two output signals comprise a first sum-output signal and a first carry-output (CO) signal, and the first output signal represents any output signal among the first sum-output signal and the first carry-output signal.

18. The method of claim 17, wherein the at least three input signals comprise a first operand signal, a second operand signal and a carry-input (CI) signal, and the first input signal represents any input signal among the first operand signal, the second operand signal and the carry-input signal.

19. The method of claim 11, wherein the at least three input signals comprise a first operand signal, a second operand signal and a carry-input (CI) signal, and the first input signal represents any input signal among the first operand signal, the second operand signal and the carry-input signal.

20. The method of claim 11, wherein the second FA is coupled to the first FA via at least both of the first output pin of the first FA and the first input pin of the second FA, wherein the first output signal of the first FA and the first input signal of the second FA have a same polarity at the first output pin of the first FA and the first input pin of the second FA, respectively.
